(19) United States
(12) Patent Application Publication
(10) Pub. No.: US 2026/0282690 A1
(43) Pub. Date: Sep. 17, 2026

(54) ARRAY SUBSTRATE, DISPLAY PANEL, AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Mengqi WANG, Beijing (CN); Tiaomei ZHANG, Beijing (CN); Ziyang YU, Beijing (CN); Zhiliang JIANG, Beijing (CN); Ming HU, Beijing (CN); Haijun QIU, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/167,844

(22) PCT Filed: Sep. 29, 2024
(86) PCT No.: PCT/CN2024/122583

§ 371 Date: Sep. 23, 2025

(30) Foreign Application Priority Data
Nov. 30, 2023 (CN) 202311635363.8

(51) Int. Cl. H10K 59/131; H10D 86/40; H10D 86/60

(52) U.S. Cl. CPC H10K 59/1315; H10D 86/443; H10D 86/60

(57) ABSTRACT

An array substrate includes: a substrate; a plurality of pixel circuits disposed on the substrate; a first conductive layer including a plurality of conductive patterns; and a second conductive layer disposed on a side of the first conductive layer away from the substrate and including a plurality of first signal lines. The plurality of pixel circuits being arranged in rows and columns. The plurality of conductive patterns are spaced apart from the plurality of pixel circuits, and a conductive pattern includes at least two contact portions arranged at intervals. The plurality of first signal lines are arranged at intervals in a first direction and all extend in a second direction; a first signal line is electrically connected to at least one conductive pattern, and the first signal line is connected to the at least two contact portions of the conductive pattern.

### CROSS-REFERENCE TO RELATED APPLICATIONS

This application is a national phase entry under 35 USC 371 of International Patent Application No. PCT/CN2024/122583, filed on Sep. 29, 2024, which claims priority to Chinese Patent Application No. 202311635363.8, filed on Nov. 30, 2023, each are incorporated herein by reference in their entirety.

### TECHNICAL FIELD

The present disclosure relates to the field of display technologies, and in particular, to an array substrate, a display panel, and a display apparatus.

### BACKGROUND

Organic light-emitting diode (OLED) display apparatuses are becoming one of the mainstream products in the display field due to their excellent performance such as self-luminous, no need for backlight source, high contrast, small thickness, wide viewing angle, high response speed, being applicable to flexible panels, wide temperature range, and simple structure and process. OLED display panels can be widely used in terminal products such as smart phones, tablet computers, televisions, and wearable devices (e.g., watches).

The OLED display panel includes an array substrate and light-emitting devices disposed on the array substrate. The array substrate includes a plurality of signal lines, and the signal lines are used for transmitting corresponding control signals to the array substrate to drive the display panel to display images. How to avoid static electricity accumulation on the signal lines is a technical problem that needs to be solved urgently in display panels.

### SUMMARY

In an aspect, an array substrate is provided. The array substrate includes a substrate, a plurality of pixel circuits, a first conductive layer and a second conductive layer. The plurality of pixel circuits are disposed on the substrate, and the plurality of pixel circuits are arranged in a plurality of rows and a plurality of columns. The first conductive layer includes a plurality of conductive patterns, the plurality of conductive patterns are spaced apart from the plurality of pixel circuits, and a conductive pattern includes at least two contact portions arranged at intervals. The second conductive layer is disposed on a side of the first conductive layer away from the substrate. The second conductive layer includes a plurality of first signal lines, and the plurality of first signal lines are arranged at intervals in a first direction and all extend in a second direction. A first signal line is electrically connected to at least one conductive pattern, and the first signal line is connected to the at least two contact portions of the conductive pattern. The first direction is a row direction in which the plurality of pixel circuits are arranged, and the second direction is a column direction in which the plurality of pixel circuits are arranged.

In some embodiments, the first conductive layer further includes a plurality of first connection lines, and the plurality of first connection lines are arranged at intervals in the second direction and all extend in the first direction. The second conductive layer further includes a plurality of data lines, and a data line is electrically connected to a column of pixel circuits; the plurality of data lines include a plurality of first data lines and a plurality of second data lines; the plurality of first data lines are respectively located on two sides of the plurality of second data lines; a first data line is connected to a first connection line. The plurality of first signal lines include a plurality of fan-out lines, and a fan-out line is electrically connected to a first connection line. The plurality of conductive patterns include a plurality of first conductive patterns, and the fan-out line is electrically connected to at least one first conductive pattern.

In some embodiments, the fan-out line includes a plurality of fan-out sub-lines arranged at intervals in the second direction, and two ends, close to each other, of two adjacent fan-out sub-lines are electrically connected to a same first conductive pattern.

In some embodiments, the first conductive pattern includes an extension portion and two contact portions, the extension portion extends in the second direction, the two contact portions are respectively connected to two ends of the extension portion in the second direction, and a size of a contact portion in the first direction is greater than a size of the extension portion in the first direction. An opening exists between two adjacent fan-out sub-lines; and the two ends, close to each other, of the two adjacent fan-out sub-lines are electrically connected to two contact portions of the same first conductive pattern, respectively.

In some embodiments, the fan-out line is continuous in the second direction; the first conductive pattern includes a plurality of contact portions and at least one extension portion alternately connected in the second direction, the extension portion extends in the second direction, and a size of a contact portion in the first direction is greater than a size of the extension portion in the first direction. The fan-out line is electrically connected to the plurality of contact portions of the first conductive pattern.

In some embodiments, the plurality of first conductive patterns are arranged in a plurality of columns in the first direction, and a column includes at least one first conductive pattern arranged in the second direction. A fan-out line is electrically connected to at least one first conductive pattern in a column.

In some embodiments, in the second direction, the plurality of first conductive patterns are evenly arranged; and an arrangement density of the plurality of pixel circuits is an integer multiple of an arrangement density of the plurality of first conductive patterns.

In some embodiments, the array substrate has a display region and a peripheral region surrounding the display region, and the plurality of pixel circuits are disposed in the display region. The array substrate further includes a first power bus, and the first power bus is located in the peripheral region and configured to be electrically connected to cathodes of light-emitting devices. The plurality of first signal lines further include a plurality of first power signal lines, and in the second direction, at least one end of the plurality of first power signal lines is electrically connected to the first power bus. The plurality of conductive patterns further include a plurality of second conductive patterns, and a first power signal line is electrically connected to at least one second conductive pattern.

In some embodiments, in the second direction, a first power signal line is electrically connected to second conductive patterns, and the second conductive patterns are evenly arranged.

In some embodiments, the plurality of conductive patterns include a plurality of first conductive patterns; a structure of the plurality of first conductive patterns is the same as a structure of the plurality of second conductive patterns; and an arrangement density of the plurality of first conductive patterns is the same as an arrangement density of the plurality of second conductive patterns.

In another aspect, a display panel is provided. The display panel includes: a plurality of light-emitting devices, and the array substrate according to any one of the above embodiments. The plurality of light-emitting devices are disposed on the array substrate, and a light-emitting device is connected to a pixel circuit of the array substrate.

In yet another aspect, a display apparatus is provided. The display apparatus includes the above display panel.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a schematic diagram of a display apparatus, in accordance with some embodiments;

FIG. 2 is a diagram showing a drive architecture of a display apparatus in accordance with some other embodiments;

FIG. 3 is a sectional view showing a structure of a display panel, in accordance with some embodiments;

FIG. 4 is a top view showing structures of a first conductive layer and a second conductive layer, in accordance with some embodiments;

FIG. 5 is a partial enlarged view of the B region in FIG. 4;

FIG. 6 is a sectional view taken along the section line A1-A1 in FIG. 5;

FIG. 7 is a diagram showing a partial structure of an array substrate, in accordance with some embodiments;

FIG. 8 is a top view showing structures of a first conductive layer and a second conductive layer, in accordance with some embodiments;

FIG. 9 is a partial enlarged view of the region C in FIG. 8;

FIG. 10 is a sectional view taken along the section line A2-A2 in FIG. 9;

FIG. 11 is a structural diagram showing a connection between a first signal line and a conductive pattern, in accordance with some embodiments; and

FIG. 12 is a top view showing a structure of an array substrate without a second conductive layer, in accordance with some embodiments.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the terms “comprise”, “comprises” and “comprising” are construed as an open and inclusive meaning, i.e., “including, but not limited to”. In the description of the specification, the term such as “one embodiment”, “some embodiments”, “exemplary embodiments”, “example” or “some examples” is intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expression “connected” and its derivative may be used. The term “connected” should be understood in a broad sense. For example, the term “connected” may represent a fixed connection, a detachable connection, or a one-piece connection, or may represent a direct connection, or may represent an indirect connection through an intermediate medium.

The phrase “A and/or B” includes the following three combinations, only A, only B, and a combination of A and B.

The phrase “applicable to” or “configured to” used herein has an open and inclusive meaning, which does not exclude devices that are applicable to or configured to perform additional tasks or steps.

In addition, the phrase “based on” or “according to” used herein is meant to be open and inclusive, since a process, step, calculation, or other action that is “based on” or “according to” one or more of the stated conditions or values may, in practice, be based on or according to additional conditions or values exceeding those stated.

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

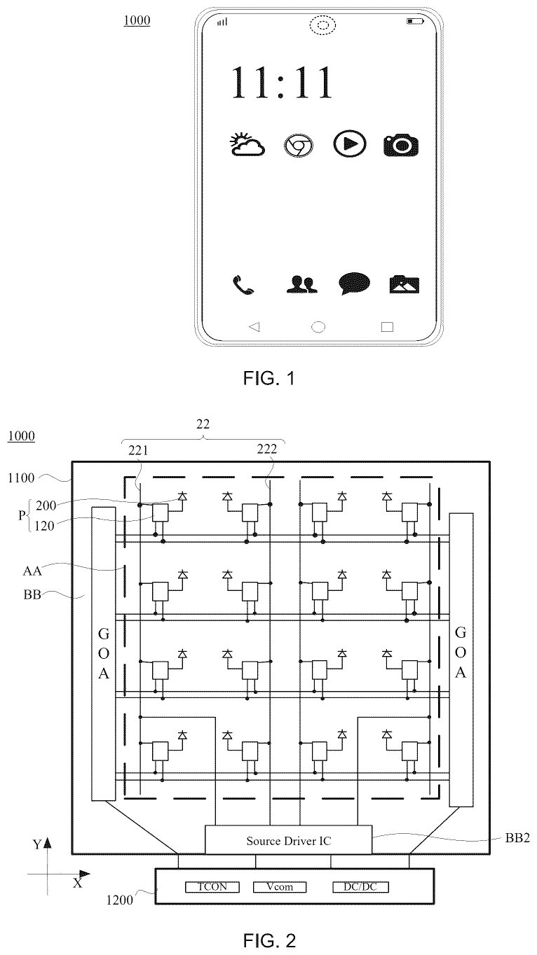

Referring to FIG. 1, embodiments of the present disclosure provide a display apparatus 1000, and the display apparatus 1000 is a product having a function of displaying images. For example, the display apparatus 1000 may be any apparatus that displays images whether in motion (e.g., videos) or stationary (e.g., static images), and whether textual or graphical.

For example, the display apparatus 1000 may be any product or component that has a display function, such as a television, a notebook computer, a tablet computer, a personal digital assistant (PDA), a mobile phone (a cell phone), a watch, a clock, a calculator, a GPS receiver/navigator, a camera, a monitor in a camera view (e.g., a monitor of a rear camera in a vehicle), a wearable device, an augmented reality (AR) device, a virtual reality (VR) device, a vehicle-mounted display, or a flight display. For example, as shown in FIG. 1, the display apparatus 1000 may be a cell phone.

From the perspective of the light-emitting type of the display apparatus 1000, the display apparatus 1000 may be an organic light-emitting diode display apparatus, a quantum dot light-emitting diode (QLED) display apparatus, or a mini/micro light-emitting diode (MLED) display apparatus. From the perspective of the form of the display apparatus 1000, the display apparatus 1000 may be a flat display apparatus, a curved display apparatus, or a foldable display apparatus. From the perspective of the shape of the display apparatus 1000, the display apparatus 1000 may have a rectangular or circular shape. The embodiments of the present disclosure are not specifically limited thereto. Some embodiments of the present disclosure will be schematically described below by taking an example in which the display apparatus is a rectangular flat organic light-emitting diode display apparatus, but the implementations of the present disclosure are not limited thereto. Any other display apparatuses may also be taken into consideration as long as the same technical concept is applied.

Referring to FIG. 2, in some embodiments, the display apparatus 1000 includes a display panel 1100 and a driver circuit board 1200. The driver circuit board 1200 may include, for example, a timing controller (TCON), a power management chip DC/DC, an adjustable resistor voltage divider circuit (for generating Vcom), and other driving circuits. The driver circuit board 1200 may further include other circuit structures, which will not be described in detail. The driver circuit board 1200 is electrically connected to the display panel 1100, and is used for transmitting control signals to the display panel 1100, thereby driving the display panel 1100 to display images. In addition, the display apparatus 1000 may further include a touch structure, an under-screen camera and an under-screen fingerprint recognition sensor, so that the display apparatus 1000 can realize various different functions such as touching, photographing, video recording, fingerprint recognition and face recognition, which are not specifically limited here.

With continued reference to FIG. 2, the display panel 1100 has a display region AA and a peripheral region BB, and the peripheral region BB is disposed on at least one side of the display region AA. For example, the peripheral region BB surrounds the display region AA.

The display region AA is a region of the display panel 1100 for displaying images, and the display region AA is provided therein with a plurality of sub-pixels P. The sub-pixels P are the smallest light-emitting units in the display panel 1100, and the sub-pixels P are used for displaying images. For example, the peripheral region BB may be used for arranging a gate driver on array (GOA) and control signal lines (such as clock signal lines, power voltage signal lines, etc.). Of course, the function of the peripheral region BB is not limited to this, which will not be described in detail in the embodiments of the present disclosure.

The plurality of sub-pixels P may emit light of different colors. For example, the plurality of sub-pixels P include red sub-pixels that emit red light, green sub-pixels that emit green light, and blue sub-pixels that emit blue light.

The plurality of sub-pixels P are arranged in a plurality of rows and a plurality of columns, each row includes sub-pixels P arranged in a first direction X, and the plurality of rows of sub-pixels P are arranged in a second direction Y. Each column includes sub-pixels P arranged in the second direction Y, and the plurality of columns of sub-pixels P are arranged in the first direction X. The first direction X and the second direction Y intersect; for example, the first direction X is perpendicular to the second direction Y.

The sub-pixel P includes a pixel circuit 120 and a light-emitting device 200. The pixel circuit 120 includes a plurality of thin film transistors (TFTs) and at least one capacitor Cst. For example, the pixel circuit 120 may be a “3T1C” circuit, a “7T1C” circuit, or an “8T1C” circuit, and the embodiments of the present disclosure are not limited thereto; any other pixel circuits may also be taken into consideration as long as the same technical concept is applied. Here, “T” represents a TFT, a number before “T” represents the number of TFTs, “C” represents a capacitor Cst, and a number before “C” represents the number of capacitors Cst.

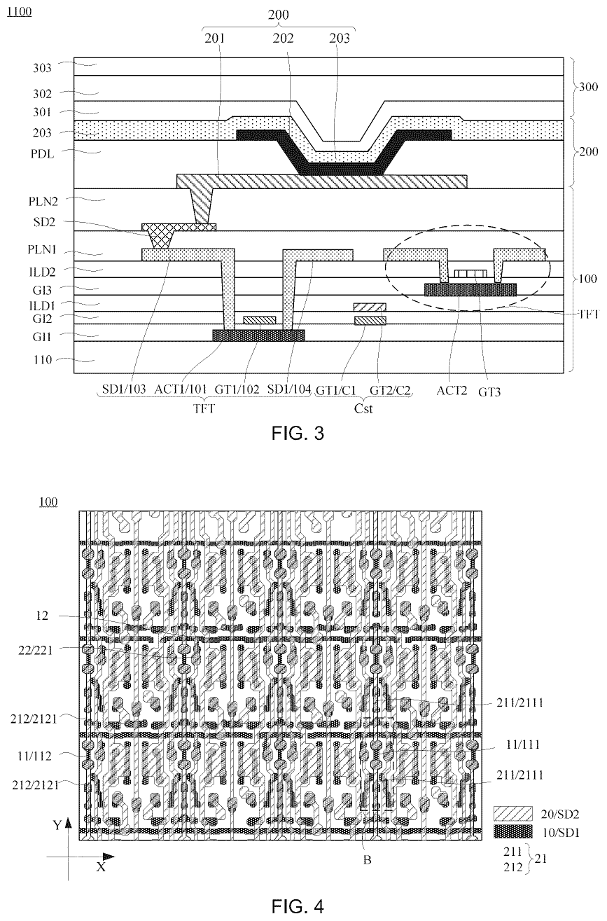

Referring to FIG. 3, in some embodiments, the display panel 1100 includes an array substrate 100, light-emitting devices 200 and an encapsulation layer 300 that are stacked. Of course, the display panel 1100 may further include functional stack layer(s) disposed on a side of the encapsulation layer 300 away from the array substrate 100. The functional stack layer(s) may be, for example, one or more of a touch function layer, an anti-reflection layer, a hardened layer, and an anti-fingerprint layer, so that the display panel can achieve corresponding functions. The embodiments of the present disclosure do not specifically limit the type and quantity of the above-mentioned functional stack layer(s).

The light-emitting device 200 includes an anode layer 201, a light-emitting functional layer 202, and a cathode layer 203 that are stacked. Cathode layers 203 of the plurality of light-emitting devices 200 are connected to each other to form a continuous whole-layer structure. The display panel 1100 may further include a pixel definition layer PDL, and the pixel definition layer PDL is disposed on a side of the anode 201 away from the array substrate 100. The pixel definition layer PDL includes a plurality of openings, and at least a portion of each light-emitting functional layer 202 is located within an opening.

The encapsulation layer 300 is configured to reduce a risk of moisture and oxygen in an external environment entering the light-emitting devices 200, to improve the service life of the display panel 1100. The encapsulation layer 300 may be an encapsulation film, or may be an encapsulation substrate. For example, as shown in FIG. 3, the encapsulation layer 300 may be an encapsulation film; in this case, the encapsulation layer 300 may include a first inorganic encapsulation layer 301, an organic encapsulation layer 302 and a second inorganic encapsulation layer 303 that are stacked in sequence.

The array substrate 100 includes a substrate 110 and pixel circuits disposed on the substrate 110. A pixel circuit is connected to a light-emitting device, and is configured to drive the light-emitting device to emit light. The substrate 110 may be a rigid substrate, and a material of the rigid substrate includes, for example, glass. Alternatively, the substrate 110 may be a flexible substrate, and a material of the flexible substrate includes, for example, any one of polyimide (PI), polycarbonate (PC), or polyvinyl chloride (PVC).

The array substrate 100 may include a plurality of conductive layers, and the plurality of conductive layers are configured to form a plurality of pixel circuits and a plurality of signal lines for driving the pixel circuits. The plurality of conductive layers may include, for example, a first semiconductor layer ACT1, a first gate conductive layer GT1, a second gate conductive layer GT2, a second semiconductor layer ACT2, a third gate conductive layer GT3, a first source-drain conductive layer SD1, and a second source-drain conductive layer SD2, which are arranged in sequence in a direction perpendicular to the substrate 110 and away from the substrate 110. Of course, the array substrate may further include other conductive layers, such as a third source-drain conductive layer, which will not be specifically limited here, as long as the same technical concept is adopted. The TFT may include a semiconductor pattern 101 located in the first semiconductor layer ACT1, a gate 102 located in the first gate conductive layer GT1, and a source 103 and a drain 104 located in the first source-drain conductive layer SD1. The capacitor Cst may include a first electrode plate C1 located in the first gate conductive layer GT1 and a second electrode plate C2 located in the second gate conductive layer GT2.

The array substrate 100 may further include an insulating layer located between adjacent conductive layers. For example, the array substrate 100 may include a first gate insulating layer GI1 located between the first semiconductor layer ACT1 and the first gate conductive layer GT1, a second gate insulating layer GI2 located between the first gate conductive layer GT1 and the second gate conductive layer GT2, a first interlayer dielectric layer ILD1 located between the second gate conductive layer GT2 and the second semiconductor layer ACT2, a second interlayer dielectric layer ILD2 located between the second semiconductor layer ACT2 and the third gate conductive layer GT3, a first planarization layer PLN1 located between the third gate conductive layer GT3 and the first source-drain conductive layer SD1, and a second planarization layer PLN2 located between the first source-drain conductive layer SD1 and the second source-drain conductive layer SD2. Of course, the array substrate 100 may further include other insulating film layers, which will not be described in detail here.

Referring to FIGS. 4, 5 and 6, the array substrate 100 provided in the embodiments of the present disclosure includes a first conductive layer 10 and a second conductive layer 20. The second conductive layer 20 is disposed on a side of the first conductive layer 10 away from the substrate 110.

The first conductive layer 10 includes a plurality of conductive patterns 11, and the plurality of conductive patterns 11 are spaced apart from the plurality of pixel circuits. The conductive patterns 11 are spaced apart from the plurality of pixel circuits, which means that the conductive patterns 11 and the pixel circuits 120 have no direct contact connections, or in other words, the conductive patterns 11 are not used for transmitting signals to the pixel circuits 120. For example, in a case where the first conductive layer 10 is the first source-drain conductive layer SD1, the pixel circuit may include sources and drains located in the first source-drain conductive layer SD1, and the conductive patterns are spaced apart from the sources and the drains of the pixel circuit. Moreover, the conductive patterns 11 are not connected to other conductive layers (e.g., the first gate conductive layer and the second gate conductive layer) on a side of the first conductive layer 10 close to the substrate, as well as the semiconductor layers.

The second conductive layer 20 includes a plurality of first signal lines 21. The plurality of first signal lines 21 are arranged at intervals in the first direction X, and all extend in the second direction Y. The first direction X is a row direction (horizontal direction in FIG. 4) in which the plurality of pixel circuits 120 are arranged, and the second direction Y is a column direction in which the plurality of pixel circuits 120 are arranged. The first direction X and the second direction Y intersect. For example, the first direction X is perpendicular to the second direction Y.

A first signal line 21 is electrically connected to at least one conductive pattern 11. Since the conductive patterns 11 are spaced apart from the pixel circuits, the first signal line 21 does not transmit an electrical signal to pixel circuit(s) through the conductive pattern(s) 11. Therefore, the positions of the conductive patterns 11 may be arbitrarily set as long as they do not interfere with other structures of the array substrate (e.g., by contact or electrical coupling).

When static electricity occurs on the first signal line 21, the static electricity will accumulate on the protrusions, corners, or other protruding sharp corners of the first signal line 21. At a position where the first signal line 21 and the conductive pattern 11 are connected, a via hole 105 is formed in an insulating layer between the first conductive layer 10 and the second conductive layer 20. A portion of the first signal line 21 is located in the via hole 105, and forms a protrusion in the via hole 105. In other words, a portion of the first signal line 21 protrudes toward a side close to the substrate 110 to form a protrusion. Based on this, the static electricity will gather at the position where the first signal line 21 and the conductive pattern 11 are connected (the portion of the first signal line 21 located in the via hole 105), and be transmitted to the conductive pattern 11, and then be released through the conductive pattern 11, thereby releasing the static electricity on the first signal line 21. As shown in FIG. 6, the conductive pattern 11 includes at least two contact portions 1112 arranged at intervals, and the first signal line 21 is connected to the at least two contact portions 1112 of the conductive pattern 11. That is, the first signal line 21 includes two positions connected to contact portions 1112. In this way, the first signal line 21 may form two protrusions at the positions connected to the conductive pattern 11, which is more conducive to the transmission of static electricity to the conductive pattern 11.

The first conductive layer 10 may be any one of the plurality of conductive layers included in the array substrate 100 as shown in FIG. 3, except a conductive layer farthest from the substrate 110. The second conductive layer 20 may be any conductive layer on the side of the first conductive layer 10 away from the substrate 110. For example, the second conductive layer 20 may be a film layer for arranging signal traces in the array substrate 100, and the first conductive layer 10 may be any conductive layer on a side of the second conductive layer 20 close to the substrate 110. For example, the first conductive layer 10 is a conductive layer adjacent to the second conductive layer 20. In this way, it may be possible to reduce a depth of the via hole in the insulating layer between the first conductive layer 10 and the second conductive layer 20 at the position where the first signal line 21 and the conductive pattern 11 are connected, and reduce the connection difficulty between the first signal line 21 and the conductive pattern 11.

For example, the first conductive layer 10 may be the third gate conductive layer GT3, and the second conductive layer 20 may be the first source-drain conductive layer SD1; alternatively, the first conductive layer 10 may be the first source-drain conductive layer SD1, and the second conductive layer 20 may be the second source-drain conductive layer SD2; alternatively, in a case where the array substrate includes the third source-drain conductive layer, the first conductive layer 10 may be the second source-drain conductive layer SD2, and the second conductive layer 20 may be the third source-drain conductive layer. Of course, the first conductive layer 10 and the second conductive layer 20 may not be adjacent conductive layers. For example, the first conductive layer 10 may be the third gate conductive layer GT3, and the second conductive layer 20 may be the second source-drain conductive layer SD2. It will be understood that the first conductive layer 10 and the second conductive layer 20 may also be other suitable combinations, which will not be described in detail in the embodiments of the present disclosure, as long as the same technical concept is adopted.

The following embodiments of the present disclosure are described by taking an example in which the first conductive layer 10 is the first source-drain conductive layer SD1 and the second conductive layer 20 is the second source-drain conductive layer SD2. However, the embodiments of the present application are not limited thereto, as long as the same technical concept is adopted.

In some embodiments, as shown in FIGS. 4 and 7, the first conductive layer 10 further includes a plurality of first connection lines 12. The plurality of first connection lines 12 are arranged at intervals in the second direction Y and all extend in the first direction X. The second conductive layer 20 further includes a plurality of data lines 22, and a data line 22 is electrically connected to a column of pixel circuits. The plurality of data lines 22 include a plurality of first data lines 221 and a plurality of second data lines 222. The plurality of first data lines 221 are respectively located on two sides of the plurality of second data lines 222 in the first direction X. For example, the plurality of first data lines 221 may be located in two edge regions AA2 of the display region AA in the first direction X, and the plurality of second data lines 222 may be located in a central region AA1 of the display region AA in the first direction X. A first data line 221 is connected to a first connection line 12. The plurality of first signal lines 21 included in the second conductive layer 20 include a plurality of fan-out lines 211, and a fan-out line 211 is electrically connected to a first connection line 12. The plurality of fan-out lines 211 may be located in the central region AA1 of the display region AA in the first direction X. Based on this, the first data line 221 located in the edge region AA2 of the display region AA in the first direction X is connected to the central region AA1 of the display region AA in the first direction X through a first connection line 12 and a fan-out line 211 in sequence, and extends outward from an edge of the central region AA1 close to the peripheral region. The above-mentioned arrangement of the data line 22 is also called Fanout In AA (FIAA) or Fanout In Panel (FIP). It is conducive to reducing a size of the peripheral region in the second direction Y, that is, reducing a width of a frame of the array substrate 100; and it is conducive to realizing a narrow bezel of the display apparatus 1000. The fan-out lines 211 are disposed in the central region AA1 of the display region AA, and are not used for transmitting data signals to the pixel circuits in the central region AA1. That is, the fan-out lines 211 are electrically insulated from the pixel circuits located on a side of the fan-out lines 211 close to the substrate 110.

In the related art, the fan-out lines 211 are arranged in a single film layer, and are not connected to any other structure except the first connection lines 12 in the display region AA, resulting in a lack of a releasing path for the created static electricity. Furthermore, the fan-out lines 211 extend between sub-pixels and need to avoid some conductive structures in the pixel circuits. Therefore, the fan-out lines 211 have certain pattern shapes, such as corners or protrusions, and the static electricity may accumulate at edges of the corners or protrusions of the fan-out lines 211. Due to the above reasons, the static electricity is easily accumulated on the fan-out lines, resulting in low reliability of the array substrate.

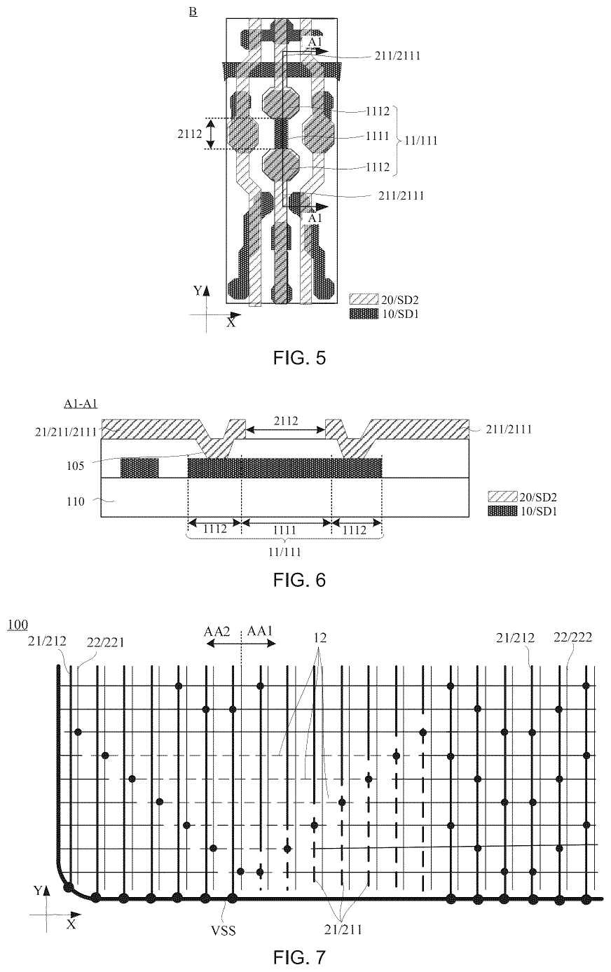

Referring to FIGS. 5 and 6, in the embodiments of the present disclosure, in order to solve the above-mentioned problem, the plurality of conductive patterns 11 include a plurality of first conductive patterns 111, a fan-out line 211 is electrically connected to at least one first conductive pattern 111, and a protrusion structure protruding toward the side close to the substrate 110 is formed at a position where the fan-out line 211 and the first conductive pattern 111 are connected. Based on this, in a case where static electricity occurs on the fan-out line 211, the static electricity will be transmitted toward the position where the fan-out line 211 and the first conductive pattern 111 are connected, and transmitted to the first conductive pattern 111, so that the static electricity is released by the first conductive pattern 111, which may improve the reliability of the array substrate.

In some embodiments, as shown in FIGS. 5 and 6, the fan-out line 211 includes a plurality of fan-out sub-lines 2111 arranged at intervals in the second direction Y. In other words, the fan-out line 211 includes a plurality of fan-out sub-lines 2111 that are disconnected from each other, and an opening 2112 exists between two adjacent fan-out sub-lines 2111. Two ends, which respectively belong to two adjacent fan-out sub-lines 2111 and are close to each other, are electrically connected to the same first conductive pattern 111. That is, two adjacent fan-out sub-lines 2111 are electrically connected through one first conductive pattern 111. In this way, when the fan-out line 211 transmits current, the current may flow through each first conductive pattern 111 connected to the fan-out line 211, ensuring that static electricity on the fan-out line 211 may be transmitted to the first conductive pattern 111 and released by the first conductive pattern 111.

Referring to FIGS. 5 and 6, the first conductive pattern 111 includes an extension portion 1111 and two contact portions 1112. The extension portion 1111 extends in the second direction Y. The two contact portions 1112 are respectively connected to two ends of the extension portion 1111 in the second direction Y. An opening 2112 exists between two adjacent fan-out sub-lines 2111. An orthogonal projection of the opening 2112 on the substrate 110 overlaps with an orthogonal projection of the extension portion 1111 on the substrate 110. Two ends, which respectively belong to two adjacent fan-out sub-lines 2111 and are close to each other, are electrically connected to two contact portions 1112 of the same first conductive pattern 111, respectively. A size of the contact portion 1112 in the first direction X is greater than a size of the extension portion 1111 in the first direction X. In this way, it is conducive to reducing the accuracy requirements of the alignment between the fan-out sub-line 2111 and the contact portion 1112, reducing the connection difficulty between the fan-out sub-line 2111 and the contact portion 1112, increasing a contact area between the fan-out sub-line 2111 and the contact portion 1112, and reducing the resistance at the connection between the fan-out sub-line 2111 and the contact portion 1112.

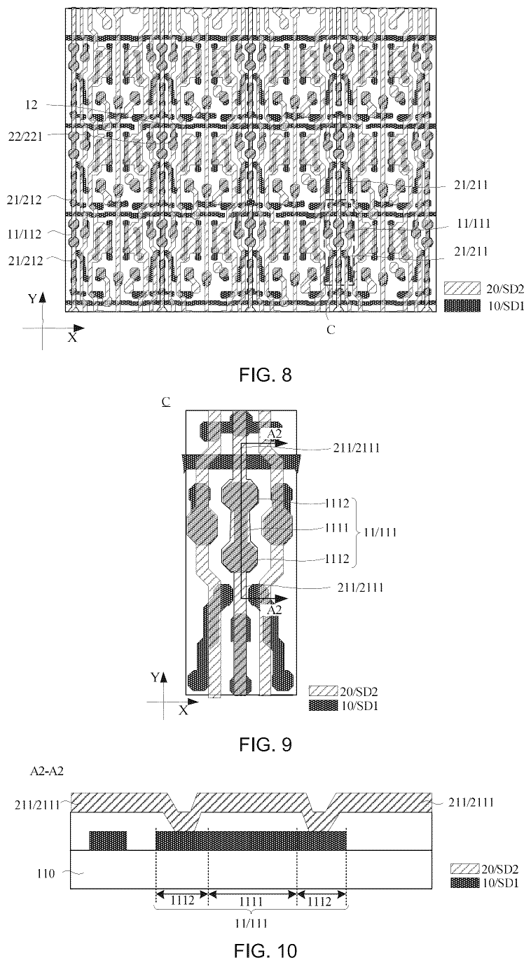

In some other embodiments, referring to FIGS. 8 and 9, the fan-out line 211 is continuous in the second direction Y, that is, there is no opening in the fan-out line 211. In this way, the fan-out line 211 is arranged in parallel with the first conductive pattern 111. The first conductive pattern 111 may release static electricity on the fan-out line 211, and may also reduce the resistance of the fan-out line 211.

Referring to FIGS. 9, 10, and 11, the first conductive pattern 111 includes a plurality of contact portions 1112 and at least one extension portion 1111 alternately connected in the second direction Y. A size of the contact portion 1112 in the first direction X is greater than a size of the extension portion 1111 in the first direction X, which is conducive to reducing the accuracy requirements of the alignment between the fan-out line 211 and the contact portion 1112, reducing the connection difficulty between the fan-out line 211 and the contact portion 1112, increasing a contact area between the fan-out line 211 and the contact portion 1112, and reducing the resistance at the connection between the fan-out line 211 and the contact portion 1112. The fan-out line 211 is electrically connected to the plurality of contact portions 1112 of the first conductive pattern 111. In other words, there are a plurality of connection points between the fan-out line 211 and the same first conductive pattern 111. In this way, it is conducive to increasing the connection reliability and stability between the fan-out line 211 and the same first conductive pattern 111, and is conducive to reducing the resistance of the fan-out line 211.

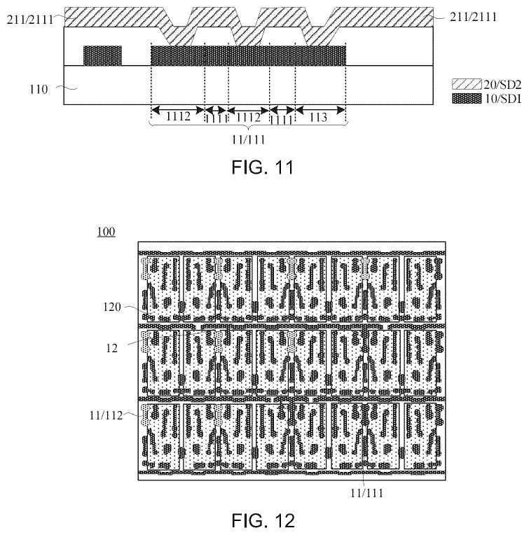

For example, two ends of the first conductive pattern 111 in the second direction Y are each provided with a contact portion 1112, and two adjacent contact portions 1112 are connected through an extension portion 1111. For example, as shown in FIG. 10, the first conductive pattern 111 includes two contact portions 1112 and one extension portion 1111. Alternatively, referring to FIG. 11, the first conductive pattern 111 may include three contact portions 1112 and two extension portions 1111. The first conductive pattern 111 may also include other quantities of contact portions 1112 and extension portions 1111, as long as the same technical concept is adopted.

In some embodiments, as shown in FIG. 12, the plurality of first conductive patterns 111 are arranged in a plurality of columns in the first direction X, and each column includes at least one first conductive pattern 111 arranged in the second direction Y. A fan-out line 211 is electrically connected to at least one first conductive pattern 111 in a column. In this way, a density of the first conductive patterns 111 connected to the fan-out line 211 may be increased. Static electricity created at any position on the fan-out line 211 will be transmitted to neighboring first conductive pattern(s) 111, so that the static electricity release effect of the fan-out line 211 is further improved. It can be understood that, in FIG. 12, in order to distinguish the first conductive pattern 111 from the second conductive pattern 112, different filling patterns are used for the two, but the two are located in the same film layer and are formed simultaneously using the same film forming process.

As shown in FIG. 12, in the second direction Y, the plurality of first conductive patterns 111 are evenly arranged, which is conducive to improving the uniformity of the first conductive patterns 111 and improving the pattern uniformity of the first conductive layer 10. The arrangement density of the pixel circuits 120 is an integer multiple of the arrangement density of the first conductive patterns 111. In other words, a distance between the first conductive patterns 111 in the second direction Y (a pitch of the first conductive patterns 111) is an integer multiple of a distance between the pixel circuits 120 in the second direction Y (a pitch of the pixel circuits 120). That is, a first conductive pattern 111 is provided on a side, away from the substrate, of every integer number of pixel circuits 120, which is conducive to improving the structural uniformity of the array substrate 100 and reducing the risk of ghosting on the display panel due to distribution differences of the first conductive patterns 111.

For example, as shown in FIG. 12, the arrangement density of the pixel circuits 120 is equal to the arrangement density of the first conductive patterns 111. In this way, the pattern uniformity of the first conductive layer 10 may be improved to a greatest extent, and the structural uniformity of the array substrate may be improved to a greatest extent.

As shown in FIG. 7, the array substrate 100 further includes a first power bus VSS, and the first power bus VSS is located in the peripheral region BB. The first power bus VSS is configured to be electrically connected to cathodes of the light-emitting devices 200. That is, the first power bus VSS is electrically connected to the cathode layer 203. The plurality of first signal lines 21 included in the second conductive layer 20 further include a plurality of first power signal lines 212. In the second direction Y, at least one end of the plurality of first power signal lines 212 is electrically connected to the first power bus VSS. The plurality of first power signal lines 212 are arranged at intervals in the first direction X, and the plurality of first power signal lines 212 all extend in the second direction Y and are electrically connected to the cathode layer. The plurality of first power signal lines 212 can reduce the resistance of the cathode layer, thereby reducing the voltage drop on the cathode layer and improving the display uniformity of the display region AA.

As shown in FIGS. 4 and 8, the plurality of conductive patterns 11 further include a plurality of second conductive patterns 112. A first power signal line 212 is electrically connected to at least one second conductive pattern 112. The first power signal line 212 protrudes toward the side close to the substrate at a position where the first power signal line 212 and the second conductive pattern 112 are connected, to form a protrusion. In a case where static electricity occurs on the first power signal line 212, the static electricity will accumulate at the protruding position of the first power signal line 212. That is, the static electricity will be transmitted to the position where the first power signal line 212 and the second conductive pattern 112 are connected, and be transmitted to the second conductive pattern 112. Tip discharge occurs at an edge or end of the second conductive pattern 112, so that the static electricity is released into an insulating layer in contact with the conductive pattern 112. The charge of static electricity is usually small, and the insulating layer (e.g., a passivation layer or a planarization layer) may absorb and release a small amount of static charge, thereby releasing the static electricity on the first power signal line 212. It can be understood that the charge of static electricity is small, and although the insulating layer is electrically insulating, it can absorb static electricity and release the static electricity.

With continued reference to FIGS. 4 and 8, in the second direction Y, a first power signal line 212 is electrically connected to multiple second conductive patterns 112, and the multiple second conductive patterns 112 are evenly arranged. In this way, a density of the second conductive patterns 112 connected to the first power signal line 212 may be increased. Static electricity created at any position on the first power signal line 212 may be transmitted to neighboring second conductive pattern(s) 112, so that the static electricity release effect of the first power signal line 212 is further improved.

In some embodiments, as shown in FIGS. 4 and 8, the plurality of conductive patterns 11 include a plurality of first conductive patterns 111 and a plurality of second conductive patterns 112. The structure of the plurality of first conductive patterns 111 and the structure of the plurality of second conductive patterns 112 are the same. That is, a shape of an orthogonal projection of the first conductive pattern 111 on the substrate is the same as a shape of an orthogonal projection of the second conductive pattern 112 on the substrate, and a size of the orthogonal projection of the first conductive pattern 111 on the substrate is equal to a size of the orthogonal projection of the second conductive pattern 112 on the substrate. The arrangement density of the plurality of first conductive patterns 111 is the same as the arrangement density of the plurality of second conductive patterns 112. In this way, the structural uniformity of the first conductive layer 10 may be further improved, and the risk of ghosting on the display panel may be reduced.

Of course, in some other embodiments, the first conductive pattern 111 and the second conductive pattern 112 may also differ. For example, in a case where the first conductive pattern 111 includes two contact portions 1112, the second conductive pattern 112 may include one contact portion, three contact portions, or another number of contact portions. The embodiments of the present disclosure are not limited thereto, as long as the same technical concept is adopted.

In some embodiments, as shown in FIG. 4, in a case where the fan-out line 211 includes the plurality of fan-out sub-lines 2111 arranged at intervals in the second direction Y, the first power signal line 212 may also include a plurality of power sub-lines 2121 arranged at intervals in the second direction Y, and the structure of the fan-out sub-lines 2111 is the same as the structure of the power sub-lines 2121. That is, a shape and size of an orthogonal projection of the fan-out sub-line 2111 on the substrate are respectively the same as a shape and size of an orthogonal projection of the power sub-line 2121 on the substrate. Alternatively, as shown in FIG. 8, in a case where the fan-out line 211 is continuous in the second direction, the first power signal line 212 may also be continuous in the second direction Y. It is conducive to improving the structural uniformity of the

It can be understood that, in some other embodiments, in a case where the fan-out line 211 includes the plurality of fan-out sub-lines 2111 arranged at intervals in the second direction Y, the first power signal line 212 may be continuous in the second direction Y. Alternatively, in a case where the fan-out line 211 is continuous in the second direction, the first power signal line 212 may include a plurality of power sub-lines arranged at intervals in the second direction Y. Of course, the embodiments of the present disclosure are not limited thereto, as long as the same technical concept is adopted.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. An array substrate, comprising:
a substrate;
a plurality of pixel circuits disposed on the substrate, the plurality of pixel circuits being arranged in a plurality of rows and a plurality of columns;
a first conductive layer including a plurality of conductive patterns, wherein the plurality of conductive patterns are spaced apart from the plurality of pixel circuits, and a conductive pattern includes at least two contact portions arranged at intervals; and
a second conductive layer disposed on a side of the first conductive layer away from the substrate and including a plurality of first signal lines, wherein the plurality of first signal lines are arranged at intervals in a first direction and all extend in a second direction; a first signal line is electrically connected to at least one conductive pattern, and the first signal line is connected to the at least two contact portions of the conductive pattern; the first direction is a row direction in which the plurality of pixel circuits are arranged; and the second direction is a column direction in which the plurality of pixel circuits are arranged.

2. The array substrate according to claim 1, wherein
the first conductive layer further includes a plurality of first connection lines, and the plurality of first connection lines are arranged at intervals in the second direction and all extend in the first direction;
the second conductive layer further includes a plurality of data lines, and a data line is electrically connected to a column of pixel circuits; the plurality of data lines include a plurality of first data lines and a plurality of second data lines; the plurality of first data lines are respectively located on two sides of the plurality of second data lines; a first data line is connected to a first connection line;
the plurality of first signal lines include a plurality of fan-out lines, and a fan-out line is electrically connected to a first connection line;
the plurality of conductive patterns include a plurality of first conductive patterns, and the fan-out line is electrically connected to at least one first conductive pattern.

3. The array substrate according to claim 2, wherein
the fan-out line includes a plurality of fan-out sub-lines arranged at intervals in the second direction, and two ends, close to each other, of two adjacent fan-out sub-lines are electrically connected to a same first conductive pattern.

4. The array substrate according to claim 3, wherein
the first conductive pattern includes an extension portion and two contact portions, the extension portion extends in the second direction, the two contact portions are respectively connected to two ends of the extension portion arranged in the second direction, and a size of a contact portion in the first direction is greater than a size of the extension portion in the first direction;
an opening exists between two adjacent fan-out sub-lines; and the two ends, close to each other, of the two adjacent fan-out sub-lines are electrically connected to two contact portions of the same first conductive pattern, respectively.

5. The array substrate according to claim 2, wherein the fan-out line is continuous in the second direction;
the first conductive pattern includes a plurality of contact portions and at least one extension portion alternately connected in the second direction, the extension portion extends in the second direction, and a size of a contact portion in the first direction is greater than a size of the extension portion in the first direction;
the fan-out line is electrically connected to the plurality of contact portions of the first conductive pattern.

6. The array substrate according to claim 2, wherein the plurality of first conductive patterns are arranged in a plurality of columns in the first direction, and a column includes at least one first conductive pattern arranged in the second direction;
a fan-out line is electrically connected to at least one first conductive pattern in a column.

7. The array substrate according to claim 6, wherein in the second direction, the plurality of first conductive patterns are evenly arranged; and an arrangement density of the plurality of pixel circuits is an integer multiple of an arrangement density of the plurality of first conductive patterns.

8. The array substrate according to claim 1, wherein the array substrate has a display region and a peripheral region surrounding the display region, and the plurality of pixel circuits are disposed in the display region;
the array substrate further comprises a first power bus, and the first power bus is located in the peripheral region and configured to be electrically connected to cathodes of light-emitting devices;
the plurality of first signal lines further include a plurality of first power signal lines, and in the second direction, at least one end of the plurality of first power signal lines is electrically connected to the first power bus;
the plurality of conductive patterns further include a plurality of second conductive patterns, and a first power signal line is electrically connected to at least one second conductive pattern.

9. The array substrate according to claim 8, wherein in the second direction, a first power signal line is electrically connected to second conductive patterns, and the second conductive patterns are evenly arranged.

10. The array substrate according to claim 8, wherein the plurality of conductive patterns include a plurality of first conductive patterns; a structure of the plurality of first conductive patterns is the same as a structure of the plurality of second conductive patterns; and an arrangement density of the plurality of first conductive patterns is the same as an arrangement density of the plurality of second conductive patterns.

11. A display panel, comprising:
the array substrate according to claim 1; and
a plurality of light-emitting devices disposed on the array substrate, wherein a light-emitting device is connected to a pixel circuit of the array substrate.

12. A display apparatus, comprising:
the display panel according to claim 11; and
a driver circuit board electrically connected to the display panel and configured to transmit control signals to the display panel.

13. The array substrate according to claim 9, wherein the plurality of conductive patterns include a plurality of first conductive patterns; a structure of the plurality of first conductive patterns is the same as a structure of the plurality of second conductive patterns; and an arrangement density of the plurality of first conductive patterns is the same as an arrangement density of the plurality of second conductive patterns.

14. The array substrate according to claim 2, wherein the array substrate has a display region and a peripheral region surrounding the display region, and the plurality of pixel circuits are disposed in the display region;
the array substrate further comprises a first power bus, and the first power bus is located in the peripheral region and configured to be electrically connected to cathodes of light-emitting devices;
the plurality of first signal lines further include a plurality of first power signal lines, and in the second direction, at least one end of the plurality of first power signal lines is electrically connected to the first power bus;
the plurality of conductive patterns further include a plurality of second conductive patterns, and a first power signal line is electrically connected to at least one second conductive pattern.

15. The display panel according to claim 11, wherein the first conductive layer further includes a plurality of first connection lines, and the plurality of first connection lines are arranged at intervals in the second direction and all extend in the first direction;
the second conductive layer further includes a plurality of data lines, and a data line is electrically connected to a column of pixel circuits; the plurality of data lines include a plurality of first data lines and a plurality of second data lines; the plurality of first data lines are respectively located on two sides of the plurality of second data lines; a first data line is connected to a first connection line;
the plurality of first signal lines include a plurality of fan-out lines, and a fan-out line is electrically connected to a first connection line;
the plurality of conductive patterns include a plurality of first conductive patterns, and the fan-out line is electrically connected to at least one first conductive pattern.

16. The display panel according to claim 15, wherein the fan-out line includes a plurality of fan-out sub-lines arranged at intervals in the second direction, and two ends, close to each other, of two adjacent fan-out sub-lines are electrically connected to a same first conductive pattern.

17. The display panel according to claim 16, wherein the first conductive pattern includes an extension portion and two contact portions, the extension portion extends in the second direction, the two contact portions are respectively connected to two ends of the extension portion arranged in the second direction, and a size of a contact portion in the first direction is greater than a size of the extension portion in the first direction;
an opening exists between two adjacent fan-out sub-lines; and the two ends, close to each other, of the two adjacent fan-out sub-lines are electrically connected to two contact portions of the same first conductive pattern, respectively.

18. The display panel according to claim 15, wherein the fan-out line is continuous in the second direction;
the first conductive pattern includes a plurality of contact portions and at least one extension portion alternately connected in the second direction, the extension portion extends in the second direction, and a size of a contact portion in the first direction is greater than a size of the extension portion in the first direction;
the fan-out line is electrically connected to the plurality of contact portions of the first conductive pattern.

19. The display panel according to claim 15, wherein the plurality of first conductive patterns are arranged in a plurality of columns in the first direction, and a column includes at least one first conductive pattern arranged in the second direction;
a fan-out line is electrically connected to at least one first conductive pattern in a column.

20. The display panel according to claim 19, wherein in the second direction, the plurality of first conductive patterns are evenly arranged; and an arrangement density of the plurality of pixel circuits is an integer multiple of an arrangement density of the plurality of first conductive patterns.
